(19) United States
(12) Patent Application Publication
(10) Pub. No.: US 2015/0180412 A1
(43) Pub. Date: Jun. 25, 2015

(54) CONTROLLABLE OSCILLATOR AND METHOD THEREOF

(71) Applicant: Realtek Semiconductor Corp., Hsinchu (TW)

(72) Inventor: Chia-Liang (Leon) Lin, Fremont, CA (US)

(73) Assignee: Realtek Semiconductor Corp., Hsinchu (TW)

(21) Appl. No.: 14/257,039

(22) Filed: Apr. 21, 2014

Related U.S. Application Data
(60) Provisional application No. 61/920,486, filed on Dec. 24, 2013.

(51) Int. Cl. H03B 5/12

(52) U.S. Cl. CPC H03B 5/1243; H03B 5/1212

(57) ABSTRACT

An apparatus and related method include a voltage-mode biasing network for receiving a reference current and outputting a biasing voltage, and an oscillator core for receiving the biasing voltage and sustaining an oscillation, wherein the voltage-mode biasing network comprises a current-to-voltage converter for converting the reference current into a reference voltage, a low-pass filter for filtering the reference voltage into a filtered reference voltage, and a source follower for receiving the filtered reference voltage and outputting a biasing voltage. The oscillator core comprises a resonator coupled to a regenerative network. In an embodiment, the current-to-voltage converter comprises at least a diode-connected transistor.

### CROSS-REFERENCE TO RELATED APPLICATION

The present application claims priority to provisional application Ser. No. 61/920,486, filed Dec. 24, 2013, the contents of which are incorporated herein by reference.

### BACKGROUND OF THE INVENTION

1. Field of the Invention

The present invention generally relates to controllable oscillators and more particularly to low-noise controllable oscillators.

2. Description of Related Art

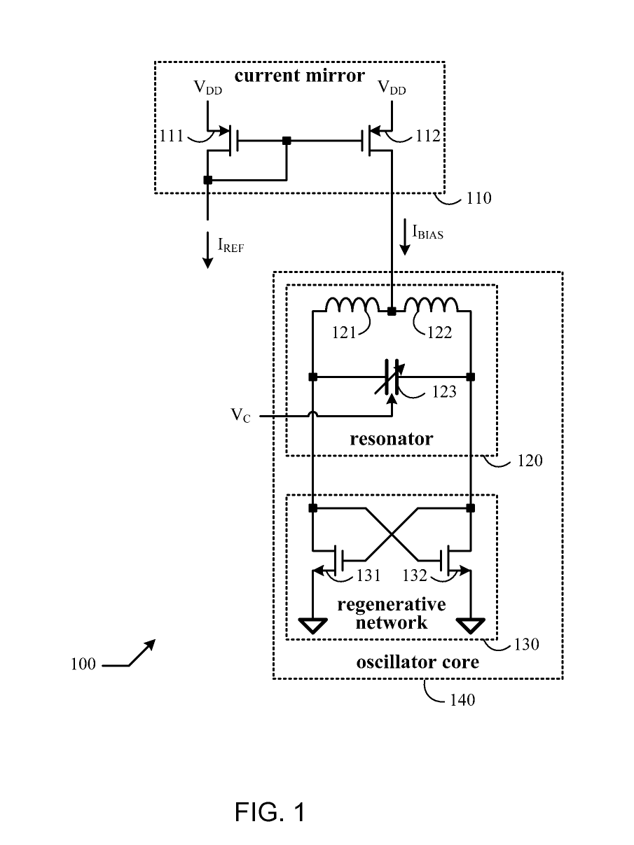

As depicted in FIG. 1, a prior art controllable oscillator 100 comprises: a current mirror 110 comprising PMOS (p-channel metal oxide semiconductor) transistors 111 and 112 for receiving a reference current I_{REF} and outputting a biasing current I_{BIAS.} The controllable oscillator 100 also includes a oscillator core 140 comprising a resonator 120 that comprises two inductors 121 and 122 and a variable capacitor 123 controlled by a control voltage V_{C} for receiving the biasing current I_{BIAS} and determining an oscillation frequency. The controllable oscillator 100 also comprises a regenerative network 130 that comprises two cross-coupled NMOS (n-channel metal oxide semiconductor transistors) 131 and 132 and couples to the resonator 120 for sustaining the oscillation.

Throughout this disclosure, V_{DD} denotes a power supply circuit node. Controllable oscillators 100 of the configuration shown in FIG. 1 are well known in prior art and thus not described in detail here. It is well known that controllable oscillators of this type suffer from performance degradation due to flicker noises contributed by MOS transistors (i.e. 111, 112, 131, and 132), which modulate on the oscillation and result in phase noise.

It is therefore desired to provide a controllable oscillator having reduced noise.

### BRIEF SUMMARY OF THIS INVENTION

An objective of this present invention is to provide a low-noise bias for an oscillator core by employing a voltage-mode biasing scheme along with low-pass filtering.

Another objective of this present invention is to suppress noises of an oscillator core by employing RC degeneration.

In an embodiment, an apparatus comprises: a voltage-mode biasing network for receiving a reference current and outputting a biasing voltage, and an oscillator core for receiving the biasing voltage and sustaining an oscillation, wherein the voltage-mode biasing network comprises a current-to-voltage converter for converting the reference current into a reference voltage, a low-pass filter for filtering the reference voltage into a filtered reference voltage, and a source follower for receiving the filtered reference voltage and outputting a biasing voltage. The oscillator core comprises a resonator coupled to a regenerative network. In an embodiment, the current-to-voltage converter comprises at least a diode-connected transistor.

In an embodiment, the resonator comprises a variable capacitor. In an embodiment, the variable capacitor is controlled by a control voltage. In another embodiment, the variable capacitor is controlled by a digital code. In an embodiment, the regenerative network comprises a pair of cross-coupled transistors. In an embodiment, the oscillator core further comprises a RC degenerating network coupled to the regenerative network. In a further embodiment, a resistor is incorporated into the current-to-voltage converter for source degeneration purpose for the diode-connected transistor.

In an embodiment, a method comprises: receiving a reference current; converting the reference current into a reference voltage using a current-to-voltage converter; filtering the reference voltage into a filtered reference voltage using a low-pass filter; establishing a biasing voltage based on the filtered reference voltage using a source follower; providing the biasing voltage to an oscillator core; establishing an oscillation frequency by controlling a variable capacitance of a resonator within the oscillator core; and sustaining an oscillation for the oscillator core by using a regenerative network. In a embodiment, the method further comprises suppressing a noise of the regenerative network using a RC degenerating network coupled to the regenerative network. In an embodiment, the current-to-voltage converter comprises at least a diode-connected transistor. In an embodiment, the resonator comprises a variable capacitor.

In an embodiment, the variable capacitor is controlled by a control voltage. In another embodiment, the variable capacitor is controlled by a digital code. In an embodiment, the regenerative network comprises a pair of cross-coupled transistors. In a further embodiment, a resistor is incorporated into the current-to-voltage converter for source degeneration purpose for the diode-connected transistor.

### DETAILED DESCRIPTION OF THE DRAWINGS

FIG. 1 shows a schematic diagram of a prior art controllable oscillator.

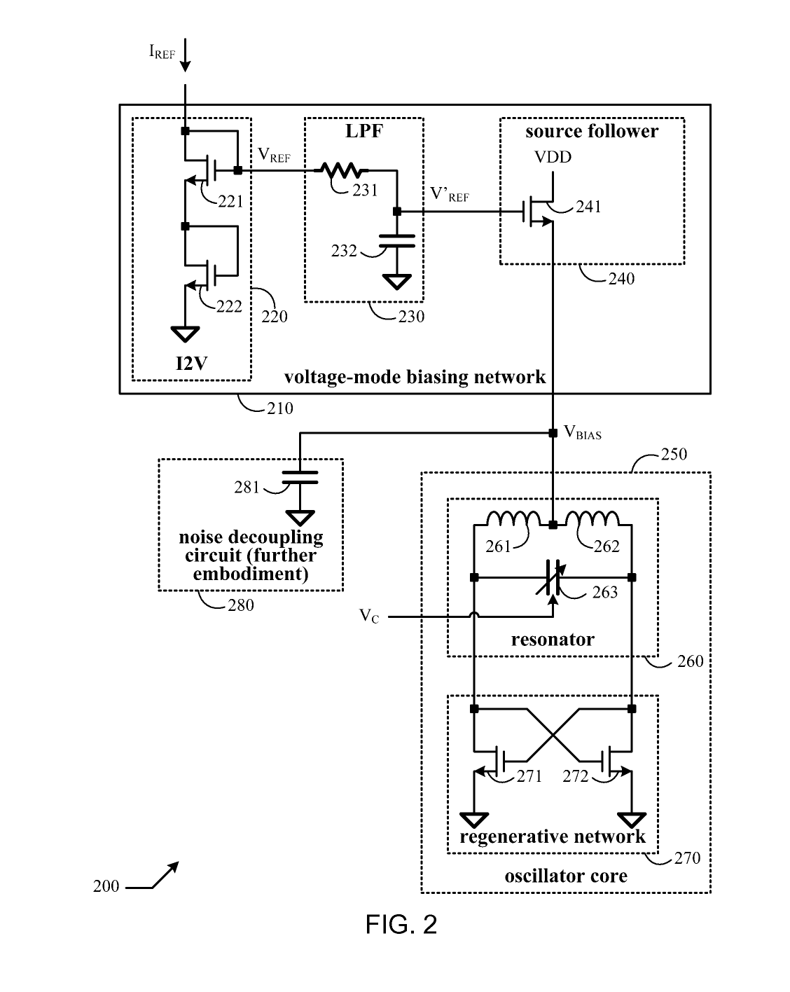

FIG. 2 shows a schematic diagram of a controllable oscillator in accordance with an embodiment of the present invention.

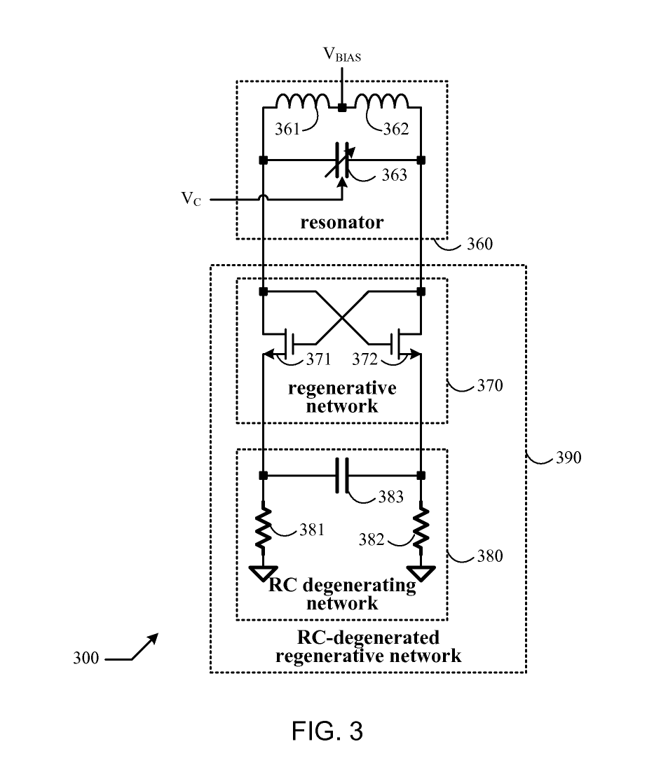

FIG. 3 shows a schematic diagram of an alternative oscillator core suitable for use for the controllable oscillator of FIG. 2.

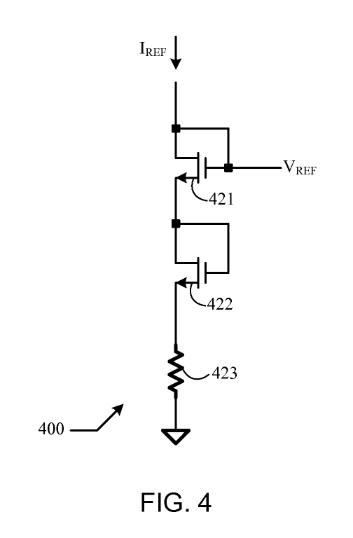

FIG. 4 shows a schematic diagram of an alternative current-to-voltage converter suitable for use for the controllable oscillator of FIG. 2.

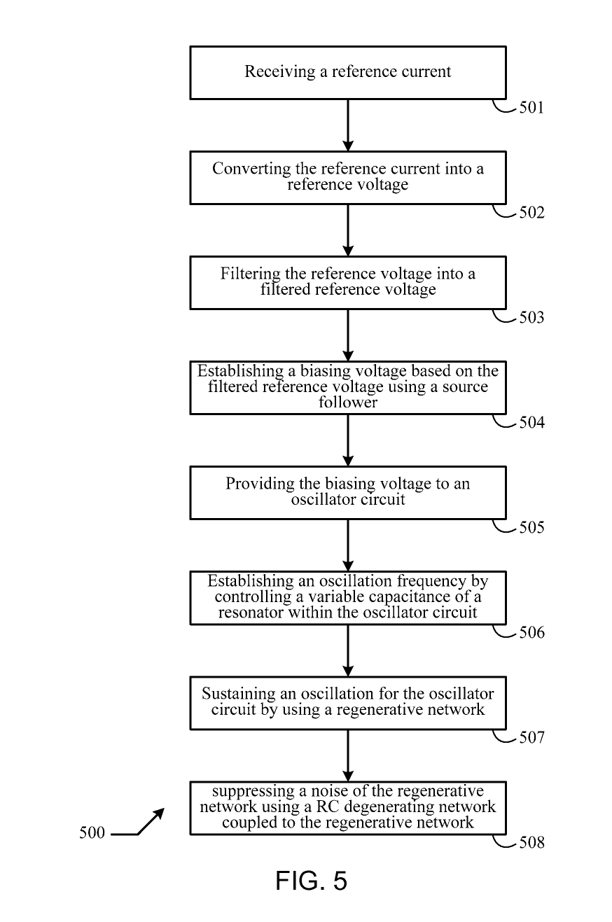

FIG. 5 shows a flow diagram for a method in accordance with an embodiment of the present invention.

### DETAILED DESCRIPTION OF THIS INVENTION

The present invention relates to controllable oscillators, and in particular to controllable oscillators having low phase noise. While the specification describe several example embodiments of the invention, it should be understood that the invention can be implemented in many ways and is not limited to the particular examples described below or to the particular manner in which any features of such examples are implemented. In other instances, well-known details are not shown or described to avoid obscuring aspects of the invention.

As depicted in FIG. 2, a controllable oscillator 200 in accordance with an embodiment of the present invention comprises: a voltage-mode biasing network 210 for receiving a reference current I_{REF} and outputting a biasing voltage V_{BIAS}, and an oscillator core 250 for receiving the biasing voltage VBIAS and sustaining an oscillation in accordance with control by a control voltage VC. The voltage-mode biasing network 210 comprises: a current-to-voltage converter (I2V) 220 comprising two diode-connected NMOS (n-channel metal oxide semiconductor) transistors 221 and 222 configured in a cascode topology for converting the reference current IREF into a reference voltage VREF; a low pass filter (LPF) 230 comprising resistor 231 and capacitor 232 for filtering the reference voltage VREF into a filtered reference voltage V′REF; and a source follower 240 comprising NMOS 241 for receiving the filtered reference voltage V′REF and outputting the biasing voltage VBIAS.

The oscillator core 250 comprises: a resonator 260 comprising two inductors 261 and 262 and a variable capacitor 263 controlled by the control voltage VC for establishing an oscillation frequency, and a regenerative network 270 comprising a pair of cross-coupled NMOS transistors 271 and 272 coupled to the resonator 260 for sustaining the oscillation.

In controllable oscillator 200, a voltage-mode biasing scheme, instead of a current-mode biasing scheme, is used to establish a biasing for oscillator core 250. In using the voltage-mode biasing scheme, the biasing voltage VBIAS is established at the output of the source follower 240, which is a low impedance circuit node by nature of a source follower. Therefore, the noise contribution from the output device of the voltage-mode biasing network 210 (which is NMOS 241) is alleviated thanks to the low impedance nature of the source follower 240. Although there may also be noise contributions from the reference current IREF and the current-to-voltage converter 220, those noise contributions are effectively filtered by LPF 230, as long as a corner of frequency of LPF 230 is substantially lower than a frequency of a flicker noise of interest. As a result, the biasing voltage VBIAS is very clean, enabling oscillator core 250 to sustain an oscillation with low phase noise.

In contrast, prior art controllable oscillator 100 of FIG. 1 uses a current-mode biasing scheme, where a biasing current IBIAS is established using current mirror 110; the noise from the output device of the current-mode biasing network 110 (which is PMOS 112) directly becomes a part of the biasing current IBIAS and cannot be alleviated, due to the high impedance nature of the current mirror 110. Therefore, controllable oscillator 200 of FIG. 2 is superior to controllable oscillator 100 of FIG. 1 in that regard.

In an alternative embodiment not shown in the figures, NMOS 222 of FIG. 2 is removed and the source terminal of NMOS 221 is directly coupled to ground. The nature of current-to-voltage conversion of I2V 220 is still preserved, even if NMOS 221 is removed.

In a further embodiment shown in FIG. 2, a noise decoupling circuit 280 comprising a capacitor 281 shunt to ground is employed and coupled to the biasing voltage VBIAS to further reduce the output impedance of the source follower 240 and thus make the biasing voltage VBIAS even cleaner.

While the voltage-mode biasing scheme of controllable oscillator 200 along with employing low-pass filtering (using LPF 230) allows effective suppression of the noise contributions from the voltage-mode biasing network 210, the noise contributions from the NMOS transistors 271 and 272 within the regenerative network 270 of the oscillator core 250 cannot be effectively suppressed. To address this issue, an alternative oscillator core 300 suitable for replacing oscillator core 250 of FIG. 2 is depicted in FIG. 3.

Referring to FIG. 3, oscillator core 300 receives the biasing voltage V_{BIAS} and sustains an oscillation in accordance with control by the control voltage V_{C}. The oscillator core 300 comprises: a resonator 360 comprising two inductors 361 and 362 and a variable capacitor 363 controlled by the control voltage V_{C} for establishing an oscillation frequency; and a RC-degenerated regenerative network 390 comprising a regenerative network 370 including a pair of cross-coupled NMOS 371 and 372 coupled to the resonator 360 for sustaining the oscillation, and a RC degenerating network 380 comprising a capacitor 383 and two resistors 381 and 382 coupled to the source terminals of NMOS 371 and 372 for providing a degeneration for the regenerative network 370. Due to the source degeneration by the RC degenerating network 380, the noise contributions from the regenerative network 370 are effectively suppressed.

In a further embodiment, an alternative current-to-voltage converter 400 can be used to replace I2V 220 of FIG. 2, in particular when oscillator core 300 of FIG. 3 is used to replace oscillator core 250 for controllable oscillator 200 of FIG. 2. Current-to-voltage converter 400 comprises two diode-connected NMOS 421 and 422 configured in a cascode topology degenerated with a source degenerating resistor 423 for converting the reference current IREF into the reference voltage VREF. Due to employing the source degenerating resistor 423, the reference voltage VREF is adjusted higher so that the biasing voltage VBIAS is also adjusted higher so as to account for the headroom taken up by the RC degenerating network 380 of the oscillator core 300 of FIG. 3, if applicable.

In an embodiment, a variable capacitor (263 of FIG. 2 and 363 of FIG. 3) comprises a varactor, whose capacitance is controlled by the control voltage VC. Vacator is well known to those of ordinary skills in the art and thus not described in detail here. In an embodiment, variable capacitor (263 of FIG. 2 and 363 of FIG. 3) comprises a combination of a varactor, having a capacitance that is controlled by the control voltage VC, and a fixed capacitor, having a capacitance that is independent of the control voltage VC.

In an alternative embodiment not shown in the figures, the variable capacitor (263 of FIG. 2 and 363 of FIG. 3) may be controlled by a digital code, instead of the control voltage VC; in this case, controllable oscillator 200 morphs into a DCO (digitally controlled oscillator). A variable capacitor controllable by a digital code can be embodied by using a parallel connection of a plurality of varactor cells, each of which is coupled to either a first voltage or a second voltage depending on a value of a respective bit of the digital code.

In a yet alternative embodiment not shown in the figures, the variable capacitor (263 of FIG. 2 and 363 of FIG. 3) is controlled by a combination of a digital code and a control voltage; in this case, the digital code serves to provide a “coarse tune” of the oscillation frequency, while the control voltage serves to provide a “fine tune” of the oscillation frequency.

In an embodiment, inductors (261 and 262 in FIG. 2; 361 and 362 in FIG. 2) have inductance values ranging from 50 pH to 5 nH, and variable capacitors (263 of FIG. 2 and 363 of FIG. 3) are of capacitance values ranging from 50 fF to 50 pF.

In an embodiment, capacitor 383 of FIG. 3 has a capacitance ranging from 10 fF to 10 pF, and resistors 381 and 382 of FIG. 3 have resistance values resistance ranging from 10-ohm to 10K-ohm.

In an embodiment, a 3-dB corner frequency of LPF 230 of FIG. 2 ranges from 1 KHz to 1 MHz.

As illustrated in flow diagram 500, a method in accordance with an embodiment of the present invention comprises: step 501 for receiving a reference current; step 502 for converting the reference current into a reference voltage; step 503 for filtering the reference voltage into a filtered reference voltage; step 504 for establishing a biasing voltage based on the filtered reference voltage using a source follower; step 505 for providing the biasing voltage to an oscillator core; step 506 for establishing an oscillation frequency by controlling a variable capacitance of a resonator within the oscillator core; step 507 for sustaining an oscillation for the oscillator core by using a regenerative network; and step 508 for suppressing a noise of the regenerative network using a RC degenerating network coupled to the regenerative network.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An apparatus comprising:
a voltage-mode biasing network for receiving a reference current and outputting a biasing voltage; and
an oscillator core for receiving the biasing voltage and sustaining an oscillation, wherein:
the voltage-mode biasing network comprises: a current-to-voltage converter for converting the reference current into a reference voltage, a low-pass filter for receiving the reference voltage and outputting a filtered reference voltage, and a source follower for receiving the filtered reference voltage and outputting the biasing voltage; and
the oscillator core comprises: a resonator for establishing an oscillation frequency, and a regenerative network coupled to the resonator for sustaining the oscillation.

2. The apparatus of claim 1, wherein the current-to-voltage converter comprises at least a diode-connected transistor.

3. The apparatus of claim 1, wherein the current-to-voltage converter comprises two diode-connected transistors configured in a cascode topology.

4. The apparatus of claim 1, wherein the current-to-voltage converter comprises at least a diode-connected transistor with a source degenerating resistor.

5. The apparatus of claim 1 further comprises a noise decoupling circuit comprising a capacitor shunt to ground coupled to the biasing voltage.

6. The apparatus of claim 1, wherein the resonator comprises a variable capacitor.

7. The apparatus of claim 6, wherein the variable capacitor is controllable via a digital code, a control voltage, or a combination of both.

8. The apparatus of claim 6, wherein the variable capacitor comprises a varactor.

9. The apparatus of claim 1, wherein the regenerative network comprises a pair of cross-coupled transistors.

10. The apparatus of claim 9, wherein the oscillator core further comprises a RC degenerating network coupled to source terminals of the pair of cross-coupled transistors.

11. A method comprising:
receiving a reference current;
converting the reference current into a reference voltage;
filtering the reference voltage into a filtered reference voltage;
establishing a biasing voltage based on the filtered reference voltage using a source follower;
providing the biasing voltage to an oscillator core comprising a resonator and a regenerative network;
establishing an oscillation frequency by controlling a variable capacitance of the resonator within the oscillator core; and
sustaining an oscillation for the oscillator core by using the regenerative network.

12. The method of claim 11, wherein converting the reference current into the reference voltage comprises using at least a diode-connected transistor.

13. The method of claim 11, wherein converting the reference current into the reference voltage comprises using at least a diode-connected transistor with a source degenerating resistor.

14. The method of claim 11, wherein converting the reference current into the reference voltage comprises using two diode-connected transistors configured in a cascode topology.

15. The method of claim 11, wherein establishing the biasing voltage based on the filtered reference voltage using the source follower further comprises: coupling the biasing voltage to a noise decoupling circuit comprising a capacitor shunt to ground.

16. The method of claim 11, wherein the variable capacitance is controlled by a control voltage.

17. The method of claim 11, wherein the variable capacitance is controlled by a digital code.

18. The method of claim 11, wherein the variable capacitance is controlled by a combination of a digital code and a control voltage.

19. The method of claim 11, wherein the regenerative network comprises a pair of cross-coupled transistors.

20. The method of claim 19 further comprising suppressing a noise of the regenerative network using a RC degenerating network coupled to source terminals of the pair of cross-coupled transistors.
